(19) United States
(12) Patent Application Publication
(10) Pub. No.: US 2011/0018454 A1
(43) Pub. Date: Jan. 27, 2011

(54) IMPROVEMENTS IN AND RELATING TO LOW POWER LIGHTING

(75) Inventor: Oleksander Melnyk, Kiev (UA)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: MELEXIS NV, Ieper (BE)

(21) Appl. No.: 12/863,424

(22) PCT Filed: Jan. 16, 2009
(86) PCT No.: PCT/IB09/00067

§ 371 Date: Oct. 5, 2010

(30) Foreign Application Priority Data
Jan. 16, 2008 (GB) 0800755.1

(51) Int. Cl. H05B 37/02; H03K 3/00

(52) U.S. Cl. 315/224; 327/108

(57) ABSTRACT

Circuitry for driving an LED light source (100) from a mains supply (10) is shown. Before reaching the driver circuit (40) for LED (100), the mains supply (10) passes via a TRIAC dimmer (20) and a rectifier (30). The TRIAC dimmer (20) may comprise a dimmer switch in series with a TRIAC. The rectifier (30) is provided to convert the AC mains supply (10) to DC. The driver circuit (40), comprises a load switch (41) for controlling the driving of the LED (100), a ballast switch (42) for controlling the driving of a ballast resistance (43) and oscillator/driver (44) for controlling the load switch (41) and ballast switch (42). The oscillator (44) enables the LED (100) to be driven in a constant or pulsed manner and the ballast (43) to be driven in a pulsed manner. The pulsed current can be utilized to ensure that the TRIAC does not shut down when there is a low throughput of power, unlike the situation wherein an equivalent power is drawn via a steady state current of less than the TRIAC threshold current.

The present invention relates to supplying power to low power lighting and in particular to supplying power to low power lighting via a TRIAC.

In an increasing number of locations, low energy light sources such as LEDs are used to provide illumination. Such light sources are typically powered from an AC mains supply via a TRIAC. This arrangement is suitable for operation as long as the current through the TRIAC is above its threshold current. Whilst this is the case if incandescent bulbs or similar are operated through dimmer switches, this is not necessarily the case if a low power light source is operated by a dimmer switch. In such circumstances when the current drops too low, the TRIAC will trigger but will not continue operating and the light source will thus become unpowered. This prevents operation over the full range of the dimmer switch.

It is therefore an object of the present invention to at least partially overcome or alleviate such problems.

According to a first aspect of the present invention there is provided a method of driving a load wherein the load is supplied with power via a TRIAC comprising the steps of drawing a pulsed current from the TRIAC, the magnitude of the current pulses being larger than the minimum current required for reliable triggering and ongoing operation of the TRIAC and the duration of the current pulses being shorter than the reaction period of the TRIAC.

In the above manner, the pulsed current ensures that the TRIAC does not shut down when there is a low throughput of power, unlike the situation wherein an equivalent power is drawn via a steady state current of less than the TRIAC threshold current.

According to the second aspect of the present invention there is provided a driver circuit suitable for being provided between a TRIAC controlled power supply and a load, the driver circuit comprising an oscillator and a ballast switch driven by the oscillator so as to draw a pulsed current from the TRIAC for driving the load.

The driver circuit of the second aspect of the present invention may be ultilised to implement the method of the first aspect of the present invention and may incorporate any features thereof as desired or as appropriate.

Preferably, the load is a light source. Most preferably, the light source is a low energy light source such as an LED.

The ballast switch is preferably provided with a ballast load of one or more resistors. A suitable first ballast resistor may be provided between the ballast switch and the mains supply. A suitable second ballast resistor may be provided between the oscillator and the ballast switch.

The method includes the step of monitoring the throughput current level. This may involve comparing the throughput current level with a predetermined threshold level. The threshold level may be substantially equal to the minimum current required for reliable triggering and ongoing operation of the TRIAC. The method as detailed in the first aspect of the present invention may only be implemented if the throughput current is below the threshold level. In the event that the throughput current is greater than the predetermined level conventional driving with a steady current may be implemented. Such functionality may be implemented by provision of a detector operable to monitor the throughput power and connect or disconnect the oscillator and ballast switch as required.

In such an embodiment, the load and the ballast switch may be driven by a single output or by separate dedicated outputs. A single oscillator may be provided for driving both the load and the ballast switch. Alternatively, separate oscillators may be provided for driving the load and the ballast switch.

The throughput power may be controlled by a power switch between the TRIAC and the power supply. The power supply may be a mains supply. The power switch may be a dimmer switch. The driver circuit may incorporate rectification means if required or desired.

According to a third aspect of the invention there is provided a light source operable in accordance with the method of the first aspect of the present invention and/or comprising a driver circuit in accordance with the second aspect of the present invention.

In order that the invention is more clearly understood specific examples will be described in greater detail below by way of example only and with reference to the following drawings, in which:

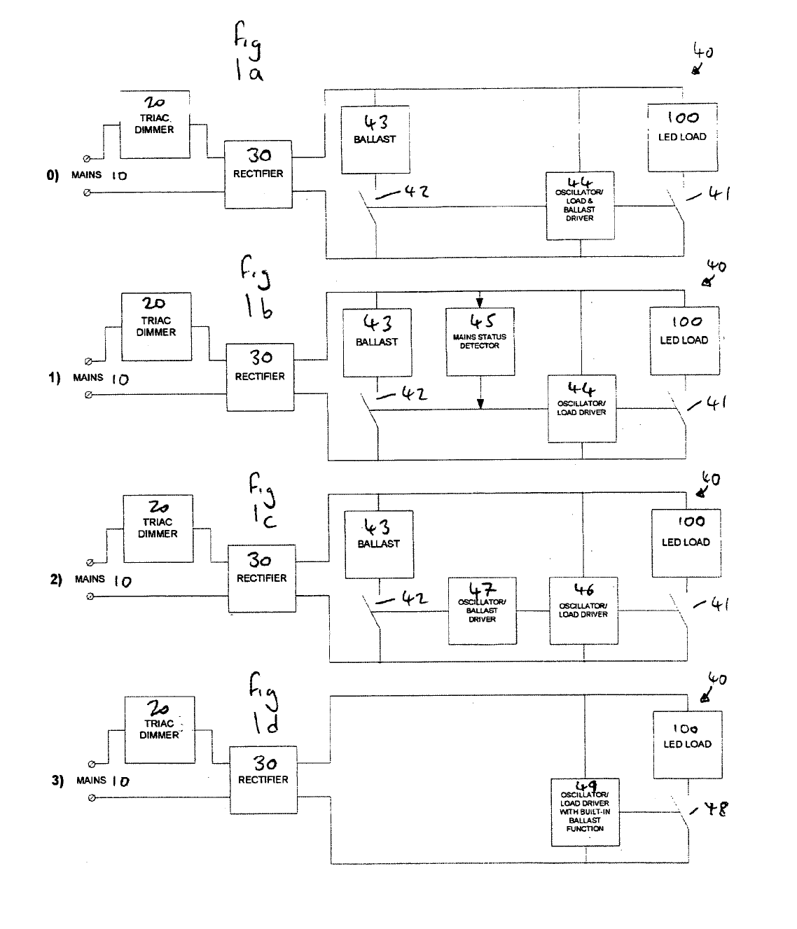

FIG. 1a shows a first embodiment of a circuit for driving a load according to the present invention;

FIG. 1b shows a second embodiment of a circuit for driving a load according to the present invention;

FIG. 1c shows a third embodiment of a circuit for driving a load according to the present invention;

FIG. 1d shows a fourth embodiment of a circuit for driving a load according to the present invention; and

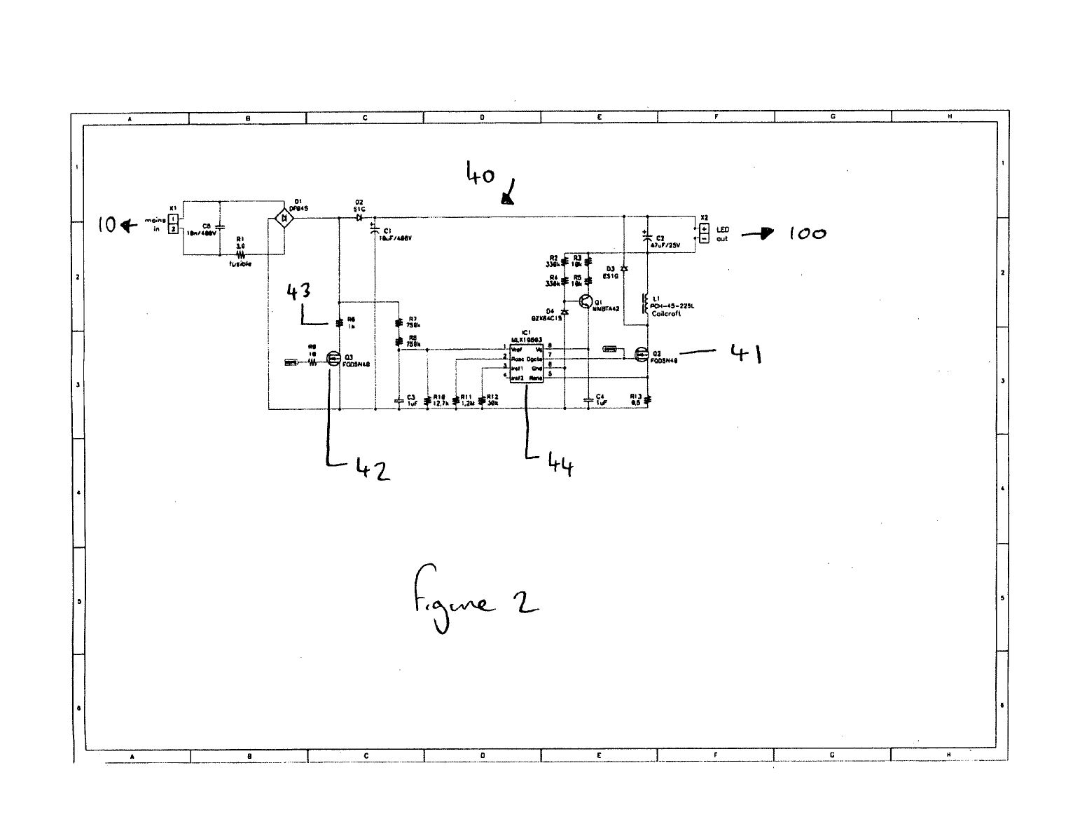

FIG. 2 shows a particular implementation of a circuit according to the first embodiment of the present invention.

Referring now to FIG. 1a, circuitry for driving an LED light source 100 from a mains supply 10 is shown. Before reaching the driver circuit 40 for LED 100, the mains supply 10 passes via a TRIAC dimmer 20 and a rectifier 30. The TRIAC dimmer 20 may comprise a dimmer switch in series with a TRIAC. The rectifier 30 is provided to convert the AC mains supply 10 to DC.

Turning now to the driver circuit 40, this comprises a load switch 41 for controlling the driving of the LED 100, a ballast switch 42 for controlling the driving of a ballast resistance 43 and oscillator/driver 44 for controlling the load switch 41 and ballast switch 42. The oscillator 44 enables the LED 100 to be driven in a constant or pulsed manner and the ballast 43 to be driven in a pulsed manner.

In conventional driver circuits, even if an oscillator 44 is provided operable to drive LED 100 in a pulsed manner such a circuit would however draw power from the mains supply at a constant rate (and thus with a constant current). If the dimmer switch is used to reduce the power supplied from the mains 10, the current level in the TRIAC will drop. If this drops below a minimum current level, the TRIAC will trigger but will not continue operating reliably and hence no power is supplied to the LED 100. In such cases the dimmer switch is thus only partly effective as below a certain power level (and hence light output) the power throughput and hence light output drops to zero.

In the present invention, this is solved by driving the ballast 43, via ballast switch 42, in a pulsed manner as controlled by the oscillator/driver 44. This causes the ballast 43 and hence the circuit 40 as a whole to draw current from the mains supply 10 via the TRIAC dimmer 20 in a pulsed manner. With a suitable choice of pulse magnitude, the pulses can be larger than the threshold current of the TRIAC so that power throughput does not cease. Similarly, with a suitable choice of pulse duration, the gaps between pulses can be shorter than the reaction period of the TRIAC so that power throughput does not cease.

By suitable choice of the size of the ballast load 43, the pulsed input power received by the oscillator driver 44 will not cause significant instability in its output.

Turning now to FIG. 1b, an alternative embodiment of driver circuit 40 is shown. This embodiment differs from that shown in FIG. 1a in the provision of a mains status detector 45. The mains status detector 45 is operable to monitor the current throughput of the driver circuit 40. If the current throughput is greater than a predetermined level (typically set at slightly above the minimum current required for reliable triggering and ongoing operation of the TRIAC) the driver circuit 40 operates conventionally. If however the current drops below the predetermined level, oscillator/driver 44 is employed to control ballast switch 42 to drive ballast load 43 in a pulsed manner as described above.

Turning now to FIG. 1c, another alternative embodiment of driver circuit 40 is shown. This embodiment differs from that shown in FIG. 1a in the provision of separate oscillator/drivers 46, 47 for driving the LED 100 and the ballast 43 respectively.

Turning now to FIG. 1d, a further alternative embodiment is shown. In this embodiment, a single oscillator/driver 49 is provided with an internal ballast load. This oscillator/driver 49 drives the LED 100 and draws input power in a pulsed manner via a single combined load/ballast switch 48.

Turning now to FIG. 2, a schematic illustration of the implementation of a circuit 40 according to the first above embodiment is shown. In this schematic, input power supply from the TRIAC is received at the upper left and the contacts for supplying power to the LED 100 are at the upper right. The load switch 41 is embodied by transistor Q2 at the lower right. The oscillator/driver 44 is the integrated circuit in the lower part of the illustration. The output of the oscillator/driver 44 is additionally fed to transistor Q3 which embodies the ballast switch 42. The ballast load 43 is embodied by R6 however a secondary ballast load R9 may be optionally provided between the oscillator/driver 44 and the ballast switch 42 to improve stability.

It is of course to be understood that the invention is not to be restricted to the details of the above embodiments which are described by way of example only.

1. A method of driving a load wherein the load is supplied with power via a TRIAC, the method comprising the steps of: drawing a pulsed current from the TRIAC, the magnitude of the current pulses being larger than the minimum current required for reliable triggering and ongoing operation of the TRIAC and the duration of the current pulses being shorter than the reaction period of the TRIAC.

2. A method as claimed in claim 1 wherein the method includes the step of monitoring the throughput current level.

3. A method as claimed in claim 2 wherein this involves comparing the throughput current level with a predetermined threshold level.

4. A method as claimed in claim 3 wherein the threshold level is substantially equal to the minimum current required for reliable triggering and ongoing operation of the TRIAC.

5. A method as claimed in claim 4 wherein the method is only implemented if the throughput current is below the threshold level.

6. A driver circuit suitable for being provided between a TRIAC controlled power supply and a load, the driver circuit comprising an oscillator and a ballast switch driven by the oscillator so as to draw a pulsed current from the TRIAC for driving the load.

7. A driver circuit as claimed in claim 6 wherein the load is a light source.

8. A driver circuit as claimed in claim 7 wherein the light source is a low energy light source such as an LED.

9. A driver circuit as claimed in claim 6 wherein the ballast switch is provided with a ballast load of one or more resistors.

10. A driver circuit as claimed in claim 9 wherein a first ballast resistor is provided between the ballast switch and the mains supply.

11. A driver circuit as claimed in claim 9 wherein a second ballast resistor is provided between the oscillator and the ballast switch.

12. A driver circuit as claimed in claim 6 wherein a detector is provided, the detector being operable to monitor the throughput power and connect or disconnect the oscillator and ballast switch as required.

13. A driver circuit as claimed in claim 6 wherein the load and the ballast switch are driven by a single output or by separate dedicated outputs.

14. A driver circuit as claimed in claim 6 wherein a single oscillator is provided for driving both the load and the ballast switch.

15. A driver circuit as claimed in claim 6 wherein separate oscillators are provided for driving the load and the ballast switch.

16. A driver circuit as claimed in claim 6 wherein the throughput power is controlled by a power switch between the TRIAC and the power supply.

17. A driver circuit as claimed in claim 16 wherein the power supply is a mains supply.

18. A driver circuit as claimed in claim 16 wherein the power switch is a dimmer switch.

19. A driver circuit as claimed in claim 6 wherein the driver circuit incorporates rectification means.

20. A light source operable in accordance with the method of claim 1 and/or comprising a driver circuit in accordance with claim 6.
